(19) United States
(12) Patent Application Publication
(10) Pub. No.: US 2022/0179125 A1
(43) Pub. Date: Jun. 9, 2022

(54) Pattern projector based on metamaterials

(71) Applicant: APPLE INC., Cupertino, CA (US)

(72) Inventors: Shen Ren, San Jose, CA (US); Lidu Huang, Danville, CA (US)

(21) Appl. No.: 17/512,700

(22) Filed: Oct. 28, 2021

Related U.S. Application Data
(60) Provisional application No. 63/120,767, filed on Dec. 3, 2020.

(51) Int. Cl. G02B 1/00; G02B 27/10; G02B 27/30; G01B 11/25; G03F 7/00

(52) U.S. Cl. CPC G02B 1/002; G02B 27/106; G03F 7/0002; G01B 11/25; G03F 7/0005; G02B 27/30

(57) ABSTRACT

An optical element includes a single transparent substrate. A first metasurface disposed on the single transparent substrate is configured to focus an input beam of optical radiation that is incident on the optical element. A second metasurface disposed on the single transparent substrate is configured to split the input beam into an array of multiple output beams.

### CROSS-REFERENCE TO RELATED APPLICATION

This application claims the benefit of U.S. Provisional Patent Application 63/120,767, filed Dec. 3, 2020, which is incorporated herein by reference.

### FIELD OF THE INVENTION

The present invention relates generally to optical devices and systems, and particularly to optical elements based on metamaterials and methods for production of such optical elements.

### BACKGROUND

Metamaterials are materials with artificial electromagnetic properties defined by the sub-wavelength physical structure of the materials, rather than by their chemical composition. Metasurfaces are a category of metamaterials that comprise a two-dimensional pattern of repeating structures, having dimensions (pitch and thickness) less than the target wavelength of the radiation with which the metasurface is designed to interact.

Metasurfaces can be designed to emulate the operation of a variety of conventional optical elements, such as lenses, polarizers, and gratings. For example, Khorasaninejad et al. describe planar lenses with high numerical aperture formed from high-aspect-ratio titanium dioxide metasurfaces, in “Metalenses at visible wavelengths: Diffraction-limited focusing and subwavelength resolution imaging,” published in Science (3 Jun. 2016: Vol. 352, Issue 6290, pages 1190-1194). The lens consists of TiO₂ nanofins formed on a glass substrate at rotation angles chosen to yield a desired phase shift in an incident light beam.

As another example, Ni et al. describe a metasurface-based diffractive optical element (DOE) in “Metasurface for Structured Light Projection over 120° Field of View,” published in Nano Letters (Vol. 20, Issue 9, pages 6719-6724, Aug. 10, 2020). The authors combine vectorial electromagnetic simulation and an interior-point method for optimization to demonstrate polarization-independent silicon-based metasurfaces that can project a collimated laser beam to a spot array in the far-field with a large field of view.

The above articles are incorporated herein by reference.

The terms “light” and “optical radiation” are used in the context of the present description and in the claims to refer to electromagnetic radiation in any of the visible, infrared, and ultraviolet wavelength ranges.

### SUMMARY

Embodiments of the present invention that are described hereinbelow provide improved optical elements based on metamaterials, as well as method for producing such optical elements.

There is therefore provided, in accordance with an embodiment of the invention, an optical element, including a single transparent substrate. A first metasurface disposed on the single transparent substrate is configured to focus an input beam of optical radiation that is incident on the optical element. A second metasurface disposed on the single transparent substrate is configured to split the input beam into an array of multiple output beams.

In a disclosed embodiment, the first metasurface is configured to collimate the multiple output beams.

In one embodiment, the single transparent substrate has opposing first and second surfaces, and the first metasurface is disposed on the first surface, while the second metasurface is disposed on the second surface. Alternatively, both of the first and second metasurfaces are disposed on a single surface of the single transparent substrate.

In a disclosed embodiment, the first and second metasurfaces include patterned dielectric materials.

There is also provided, in accordance with an embodiment of the invention, a projection module including the optical element described above and a light source, which is configured to direct an input beam of optical radiation toward the optical element, which projects the input beam into a structured light pattern of multiple output beams.

There is further provided, in accordance with an embodiment of the invention, a method for producing an optical element. The method includes forming on a transparent substrate a first metasurface configured to focus an input beam of optical radiation that is incident on the optical element, and forming on the transparent substrate a second metasurface configured to split the input beam into an array of multiple output beams.

In some embodiments, forming the first and second metasurfaces includes depositing and patterning dielectric materials on one or more surfaces of the transparent substrate. In a disclosed embodiment, depositing and patterning the dielectric materials includes depositing a layer of a dielectric material on the transparent substrate, and applying to the deposited layer a pattern having features finer than a wavelength of the input beam using a lithographic technique, selected from a group of techniques consisting of ultraviolet lithography, e-beam lithography, and nano-imprint lithography.

The present invention will be more fully understood from the following detailed description of the embodiments thereof, taken together with the drawings in which:

### BRIEF DESCRIPTION OF THE DRAWINGS

FIG. 1A is a schematic side view of a projection module based on an optical element having two metasurfaces, in accordance with an embodiment of the invention;

FIG. 1B is a schematic side view of an optical element comprising metamaterials, in accordance with an alternative embodiment of the invention;

FIG. 2 is a schematic frontal view of a refractive metasurface, in accordance with an embodiment of the invention;

FIG. 3 is a schematic pictorial view of a diffractive metasurface, in accordance with an embodiment of the invention;

FIG. 4 is a flow chart that schematically illustrates a method for producing an optical element, in accordance with an embodiment of the invention; and

FIG. 5 is a flow chart that schematically illustrates a method for producing an optical element, in accordance with another embodiment of the invention.

### DESCRIPTION OF EMBODIMENTS

Optical pattern projectors are used in a variety of applications. For example, in some depth mapping devices based on structured light, a projection module projects a pattern of spots onto a target scene, and an image of the projected pattern is processed to find the depth coordinates of the points in the target scene. Typically, the projection module comprises a light source, a lens system to collimate the beam produced by the light source, and a diffractive optical element (DOE) to split the collimated beam into an array of output beams, which form the spots on the target scene. The need to use both a lens and a DOE increases the size, weight, and cost of the projection module.

Embodiments of the present invention address this problem by using a single optical element, based on metamaterials that are deposited on a single transparent substrate, to perform both the focusing (for example, collimation) and patterning functions: A first metasurface formed on the substrate collimates an input beam of optical radiation that is incident on the optical element, and a second metasurface formed on the same substrate splits the input beam into an array of multiple output beams. The two metasurfaces may be formed respectively on opposing surfaces of the substrate, or they may be formed one over the other on the same surface. Typically (although not necessarily), the second metasurface emulates the operation of a DOE in splitting the input beam into output beams at well-defined angles, while the first metasurface collimates the output beams. The use of two different metasurfaces on the same substrate substantially reduces the size and weight of projection modules in which this novel optical element is used.

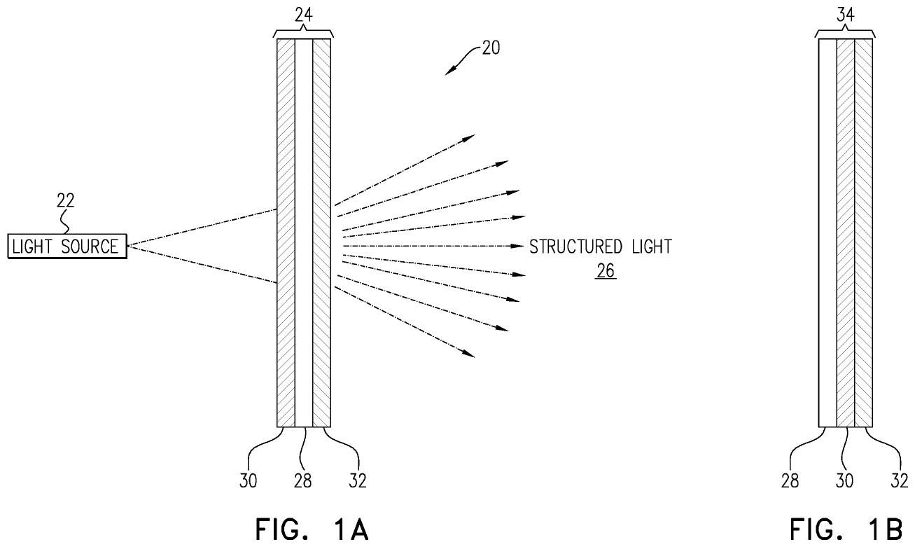

FIG. 1A is a schematic side view of a projection module 20 based on an optical element 24 of this sort, in accordance with an embodiment of the invention. Optical element 24 comprises a single transparent substrate 28, such as a glass blank. A refractive metasurface 30 is disposed on one surface of substrate 28, and a diffractive metasurface 32 is disposed on the opposing surface of the substrate. A light source 22, such as a laser, directs an input beam of optical radiation toward the optical element, which projects the input beam into a structured light pattern of multiple output beams extending over a volume 26 in space.

FIG. 1B is a schematic side view of an optical element 34, in accordance with an alternative embodiment of the invention. Optical element 34 performs similarly to optical element 24 (FIG. 1A), but both the refractive metasurface 30 and diffractive metasurface 32 are formed on the same surface of substrate 28.

FIG. 2 is a schematic frontal view of refractive metasurface 30, which can be used in the optical elements of FIGS. 1A and 1B, in accordance with an embodiment of the invention. The effective refractive index of metasurface 30 varies radially, with higher refractive index at its center. This variation can be achieved by varying the filling ratio of the metasurface layer, for example, or by depositing nanowire structures 40, 42, 44 of different diameters, sizes and/or densities. Alternatively, refractive metasurface 30 may be similar in construction to the planar lenses described in the above-mentioned article by Khorasaninejad et al.

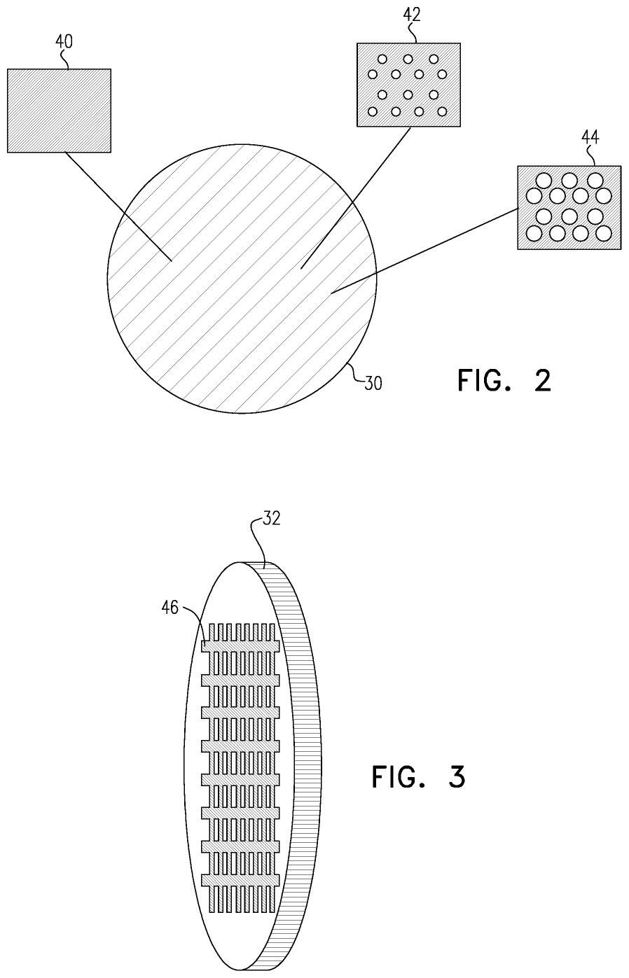

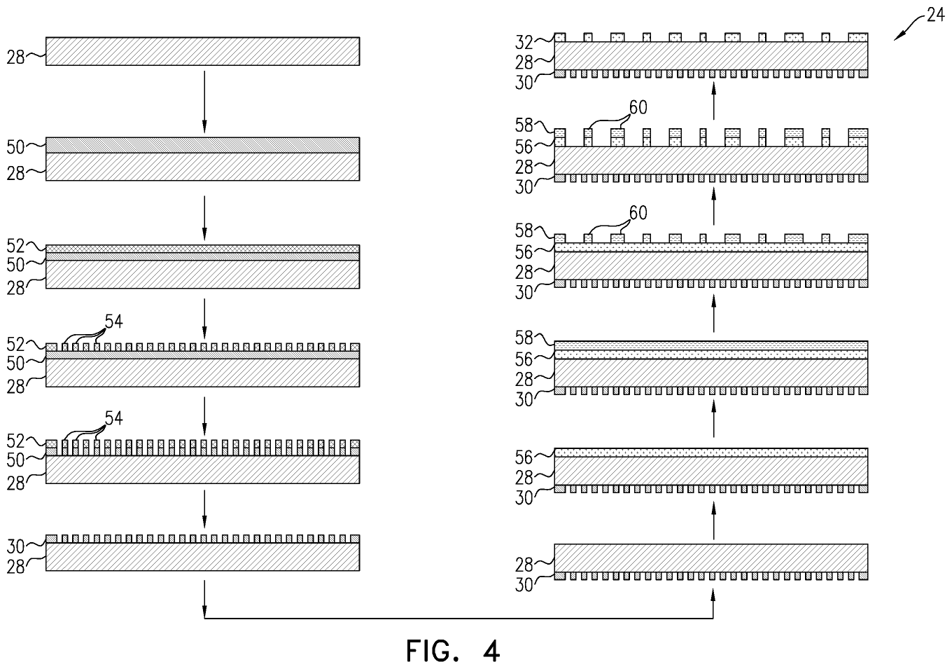

FIG. 3 is a schematic pictorial view of diffractive metasurface 32, which can be used in the optical elements of FIGS. 1A and 1B, in accordance with an embodiment of the invention. In the pictured embodiment, diffractive metasurface 32 functions as a two-dimensional wire grid grating 46 (shown in the figure only for purposes of illustration, and not to scale). Alternatively, diffractive metasurface 32 may be configured to generate an irregular pattern of output beams. Further alternatively or additionally , diffractive metasurface 32 may be similar in construction to the metasurface-based DOE described in the above-mentioned article by Ni et al.

FIG. 4 is a flow chart that schematically illustrates a method for producing an optical element, in accordance with an embodiment of the invention. This method may be used, for example, in producing optical element 24 (FIG. 1A), with metasurfaces 30 and 32 on opposing surfaces of a transparent substrate, such as glass. The metasurfaces may advantageously comprise patterned dielectric materials, such as TiO₂ or SiO₂. Alternatively or additionally, the metasurfaces may comprise patterned semiconductor or metal materials.

In the method of FIG. 4, an optical layer 50 is deposited on a first surface of substrate 28. For example, layer 50 may comprise a thin dielectric film, which is deposited by a technique such atomic layer deposition or plasma-enhanced chemical vapor deposition, so that the resulting layer is highly conformal and smooth. Optical layer 50 is overlaid with a spin mask layer 52, such as a suitable polymer resist. Mask layer 52 is patterned with metastructure features 54 that are finer than the wavelength of the input beam with which optical element 24 is to be used. The pattern can be applied using a precision lithographic technique, such as ultraviolet lithography, e-beam lithography, or nano-imprint lithography. After developing the patterned resist of layer 52, underlying optical layer 50 is etched to create the actual metastructures of the metasurface, and the remaining mask material is removed, leaving metasurface 30.

To produce metasurface 32, the substrate is flipped over, and the preceding steps are repeated to deposit the desired metastructures on the opposing surface of substrate 28: An optical layer 56 is deposited on substrate 28, followed by a mask layer 58. A pattern of metastructure features 60 is lithographically applied to mask layer 58 and is then etched into optical layer 56. The pattern of features 60 will, of course, be different from that used in metasurface 30, and the composition of optical layer 56 may be different, as well; but otherwise the fabrication process is similar or identical. Upon removal of mask layer 58 and conclusion of the processing of metasurface 32, optical element 24 is ready for use.

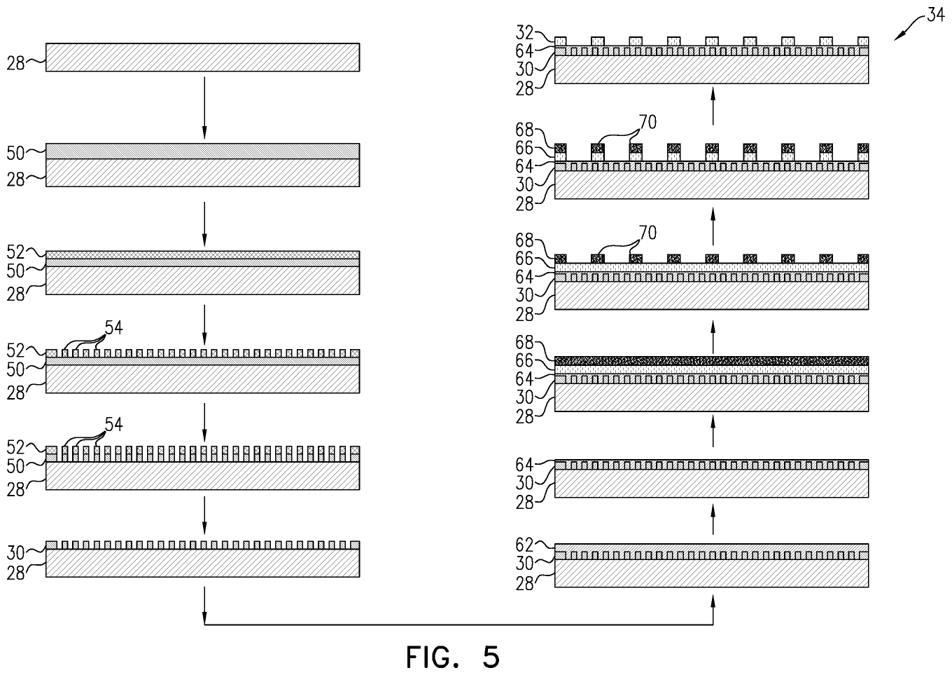

FIG. 5 is a flow chart that schematically illustrates a method for producing an optical element, in accordance with another embodiment of the invention. This method may be used, for example, in producing optical element 34 (FIG. 1B), with both metasurfaces 30 and 32 on the same surface of substrate 28. The steps involved in producing metasurface 30 are similar to those in the method of FIG. 4. At this stage, however, substrate 28 is not flipped over. Rather, the metastructures in metasurface 30 are covered with a spin-on layer 62 of lower refractive index. Layer 62 is planarized to form a base 64 for deposition and patterning of the second metasurface. An optical layer 66 is deposited on base 64, followed by a mask layer 68. A pattern of metastructure features 70 is lithographically applied to mask layer 68 and is then etched into optical layer 66. Upon removal of mask layer 68 and conclusion of the processing of metasurface 32, optical element 34 is ready for use.

Although the examples described above relate specifically to optical elements with two metamaterial layers for purposes of focusing and beam splitting, the principles of the present invention may similarly be applied, mutatis mutandis, in producing other sorts of optical elements on which two or even more metamaterial layers are formed. It will thus be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. An optical element, comprising:
a single transparent substrate;
a first metasurface disposed on the single transparent substrate and configured to focus an input beam of optical radiation that is incident on the optical element; and
a second metasurface disposed on the single transparent substrate and configured to split the input beam into an array of multiple output beams.

2. The optical element according to claim 1, wherein the first metasurface is configured to collimate the multiple output beams.

3. The optical element according to claim 1, wherein the single transparent substrate has opposing first and second surfaces, and the first metasurface is disposed on the first surface, while the second metasurface is disposed on the second surface.

4. The optical element according to claim 1, wherein both of the first and second metasurfaces are disposed on a single surface of the single transparent substrate.

5. The optical element according to claim 1, wherein the first and second metasurfaces comprise patterned dielectric materials.

6. A projection module comprising:
the optical element according to claim 1; and
a light source, which is configured to direct an input beam of optical radiation toward the optical element, which projects the input beam into a structured light pattern of multiple output beams.

7. A method for producing an optical element, the method comprising:
forming on a transparent substrate a first metasurface configured to focus an input beam of optical radiation that is incident on the optical element; and
forming on the transparent substrate a second metasurface configured to split the input beam into an array of multiple output beams.

8. The method according to claim 7, wherein the first metasurface is configured to collimate the multiple output beams.

9. The method according to claim 7, wherein the transparent substrate has opposing first and second surfaces, and wherein the first metasurface is formed on the first surface, while the second metasurface is formed on the second surface.

10. The method according to claim 7, wherein both of the first and second metasurfaces are formed on a single surface of the transparent substrate.

11. The method according to claim 7, wherein forming the first and second metasurfaces comprises depositing and patterning dielectric materials on one or more surfaces of the transparent substrate.

12. The method according to claim 11, wherein depositing and patterning the dielectric materials comprises:
depositing a layer of a dielectric material on the transparent substrate; and
applying to the deposited layer a pattern having features finer than a wavelength of the input beam using a lithographic technique, selected from a group of techniques consisting of ultraviolet lithography, e-beam lithography, and nano-imprint lithography.
